(19) United States
(12) Patent Application Publication
(10) Pub. No.: US 2007/0236897 A1
(43) Pub. Date: Oct. 11, 2007

(54) Electronic device for at least a driving module

(75) Inventor: Jui-Lin Chen, Taipei (TW)

Correspondence Address: EDWARDS ANGELL PALMER & DODGE LLP, P.O. BOX 55874, BOSTON, MA, 02205, US

(73) Assignee: Inventec Corporation, Taipei (TW)

(21) Appl. No.: 11/394,710

(22) Filed: Mar. 31, 2006

(51) Int. Cl. H05K 5/00

(52) U.S. Cl. 361/752

(57) ABSTRACT

An electronic device for at least a driving module is disclosed. The electronic device includes a body having an opening, an accommodating space corresponding to the opening, and a first fixing structure installed adjacent to the accommodating space. The electronic device further includes a connecting box for accommodating the driving module and for allowing the driving module to be replaced through the opening into the accommodating space. The connecting box includes a second fixing structure corresponding to the first fixing structure for fixing the connecting box in the body.

### BACKGROUND OF THE INVENTION

1. Field of the Invention

This invention relates to an electronic device for at least a replaceable driving module, and more particularly, to an electronic device for driving modules of different sizes.

2. Description of Related Art

With the development of information technologies, computers can operate at higher and higher speed and have lower and lower costs, and can be widely applied to varieties fields. For example, a computer server for an enterprises has functions different from those of a desktop personal computer. An electronic device such as the computer server comprises a central processing units (CPU), a chip set and a memory, all of which are installed on a main circuit board. The computer server further comprises other electronic components such as a hard drive. The computer server functions independently, and can be integrated into a rack to form a stackable and connectable server rack. Such a replaceable server rack is called blade server. The blade server has a height of 1.75 (1U) or 3.5 (2U).

FIG. 1 is a schematic diagram of a blade server 1 according to the prior art. The blade server 1 comprises a body 11 having a bottom board 111, a main circuit board 13 installed on the bottom board 111 and having a supporting base 131, a plurality of driving modules 15 installed in a region encircled by the supporting base 131, and a plurality of electronic components 17. The driving modules 15 are connected to the main circuit board 13 through connectors (not shown). At least one of the driving module 15 can be a hard drive, which is fixed to the blade server 1. To replace the driving module 15, a rack of the blade server 1 has to be drawn first, and the driving module 15 can therefore be detached from the supporting base 131 for replacement, which is complicated. Moreover, the driving modules 15 installed in the blade server 1 have to have one identical size. For example, the driving modules 15 of the blade server 1 are all in the size of 2.5 inches or are all in the size of 3.5 inches. Therefore, another driving module having a size different from the sizes of the driving module 15 already installed on the blade server 1 can not be further installed in the blade server 1.

In order to overcome the above problem, another blade server 2 supporting a hot-swappable driving module 27 is brought to the market. As shown in FIG. 2, the blade server 2 comprises a body 21 having an opening 211 and a bottom board 213, a main circuit board 23 installed on the bottom board 213, a rack 25 also installed on the bottom board 213, and a driving module 27 accommodated in the rack 25 and having a movable handler 271. The driving module 27 is for example a hard drive, which can be pushed and acquired from the rack 25 by opening the movable handler 271, so as to solve the above problem that the driving module 15 can not detached from the blade server 1 unless the driving module 15 is detached from the supporting base 131 first.

However, like the blade server 1, the blade server 2 is also designed to accommodate the driving modules of only one size. Therefore, the blade server 2, if is designed to accommodate the driving modules 27 in the size of 2.5 inches, can not accommodate another driving module in the size of 3.5 inches. The blade server 2 lacks expansibility.

Therefore, how to solve the drawbacks of the prior art is becoming one of the most important issues in the art.

### SUMMARY OF THE INVENTION

In views of the above-mentioned problems of the prior art, it is a primary objective of the present invention to provide an electronic device with replaceable driving modules, for reducing the manufacturing cost.

It is another objective of the present invention to provide an electronic device with replaceable driving modules, for supporting driving modules in different sizes.

It is a further objective of the present invention to provide an electronic device with replaceable driving modules, for supporting a hot-swappable function.

It is still another objective of the present invention to provide an electronic device with replaceable driving modules, for simplifying the assembling and detaching steps.

It is still another objective of the present invention to provide an electronic device with replaceable driving modules, the electronic device having a simple structure and design flexibility.

To achieve the above-mentioned and other objectives, an electronic device for at least a driving module is provided according to the present invention. The electronic device includes a body having an opening, an accommodating space corresponding to the opening, and a first fixing structure installed adjacent to the accommodating space; and a connecting box for accommodating the driving module and for allowing the driving module to be replaced through the opening into the accommodating space, the connecting box having a second fixing structure corresponding to the first fixing structure for fixing the connecting box in the body.

The first fixing structure includes a screw pole, a first positioning member, and a plurality of second positioning members, all of which are installed around a peripheral region of the accommodating space. The first positioning member is one selected from the group consisting of a protruding plate, a protruding bump and a stopper. The second positioning member is one selected from the group consisting of a protruding plate, a protruding bump, a stopper, a protruding rib and a protruding dot. The second fixing structure includes an engaging member installed on a side surface of the connecting box, and an elastic member. The engaging member is one selected from the group consisting of a screw and a screw bolt. The elastic member is one selected from the group consisting of a metal leaf spring, a leaf steel, a spring slice and a spring. The electronic device further includes a housing installed on a side of the connecting box, the housing including a handler and a pressing member. The electronic driving module is a hard drive. The electronic device further includes a rear board for electrically connecting the body and the driving module in the connecting box. The rear board is a circuit board and has at least a connector.

In contrast to the prior art, the connecting box can be drawn form the electronic device and replaced with another connecting box having driving modules of different sizes, without replacing the electronic device, so as to solve the problems of the prior art that two driving modules if having different sizes are not replaceable with each other and that the electronic device has to be changed in accordance with the change of the driving module. Therefore, the present invention has a low manufacturing cost.

Moreover, the connecting box can be designed flexibly according to the sizes of the driving modules installed in the electronic device, so as to solve the problems of the prior art that the driving modules installed in the electronic device can have only one size. Therefore, the present invention can support driving modules in different sizes.

Further, the electronic device has a rear board installed on the connecting box for providing a hot-swappable function to the driving module. Moreover, because the electronic device has the engaging member and the elastic member, and the connecting box can be drawn from the electronic device by rotating the engaging member and pressing the elastic member, the electronic device of the present invention can provide simple assembling and detaching steps.

Therefore, through the use of the electronic device of the present invention, the problems of the prior art can be solved. Moreover, the electronic device provides the connecting box a hot-swappable function and can support the driving modules even if the driving modules have different sizes, so the present invention is evaluated to be of high industrial utility.

### BRIEF DESCRIPTION OF DRAWINGS

The invention can be more fully understood by reading the following detailed description of the preferred embodiments, with reference made to the accompanying drawings, wherein:

FIG. 1 is a schematic diagram of a blade server according to the prior art;

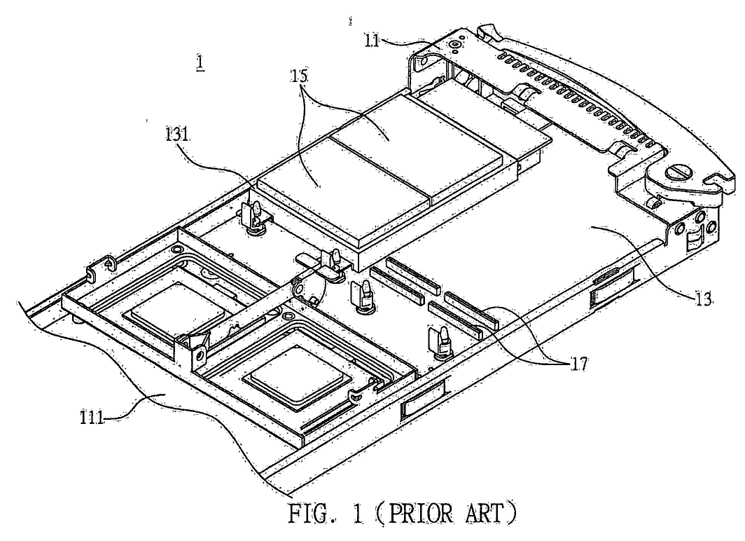

FIG. 2 is a schematic diagram of a blade server supporting a hot-swappable hard drive according to the prior art;

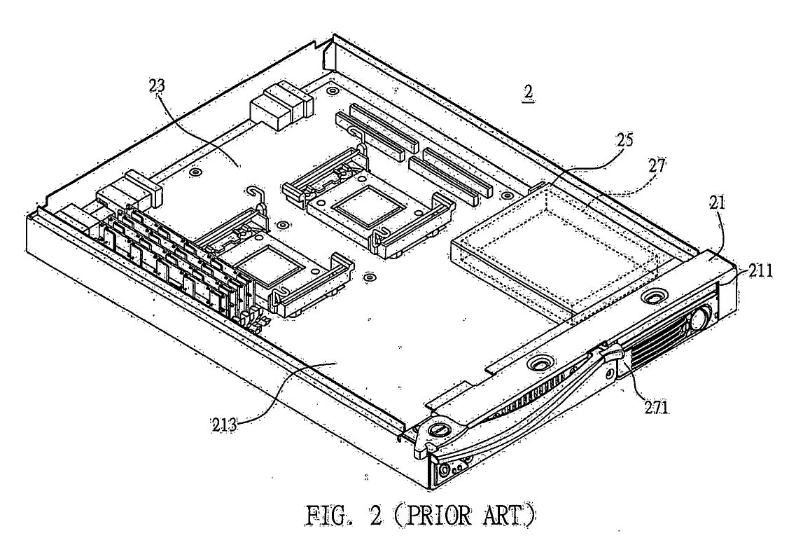

FIG. 3 is a schematic diagram of a connection box of an electronic device of the present invention;

FIG. 4A is a schematic diagram of an electronic device of the present invention;

FIG. 4B is another schematic diagram of FIG. 4A;

FIG. 5 is a schematic diagram of a connecting box of an electronic device of the present invention; and

FIG. 6 is a schematic diagram of an electronic device of another embodiment.

### DETAILED DESCRIPTION OF PREFERRED EMBODIMENTS

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

### First Embodiment

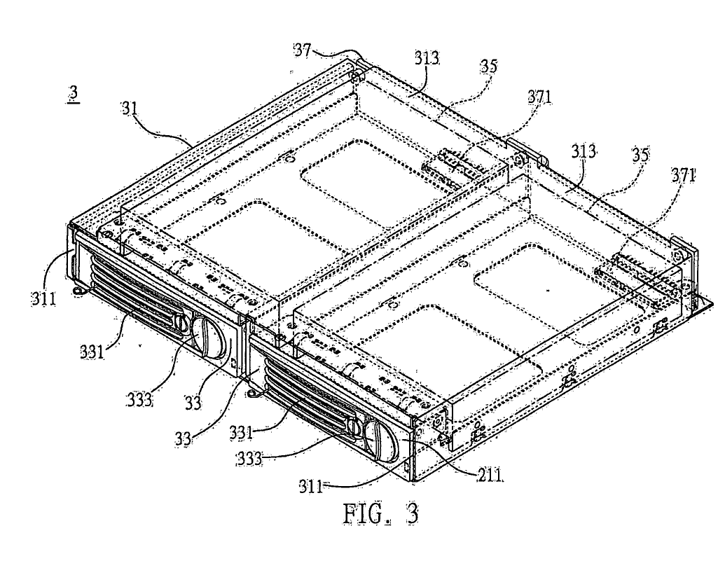

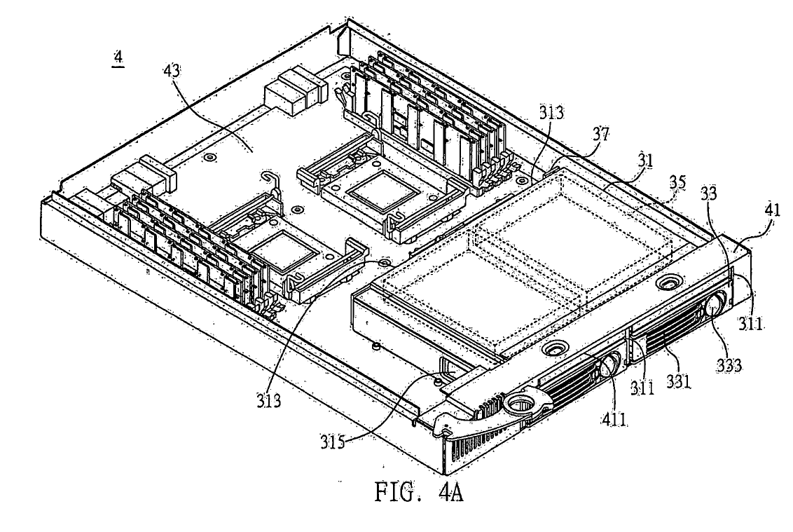

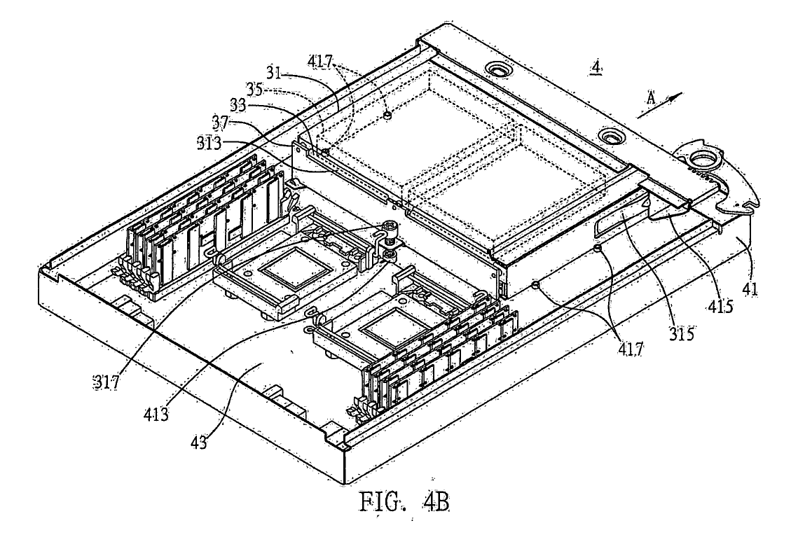

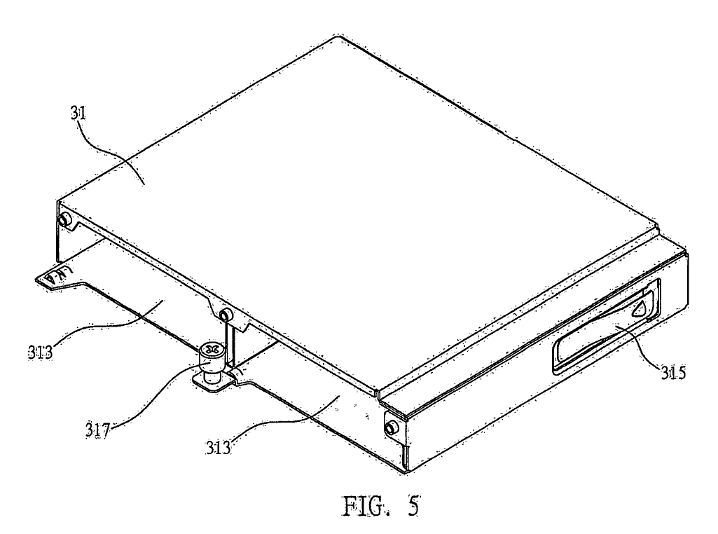

Please refer to FIG. 3 to FIG. 6. FIG. 3 is a schematic diagram of a connecting box 31 of an electronic device 4 of the present invention. The connecting box 31 is used for accommodating a driving module 35. FIG. 4A is a schematic diagram of the electronic device 4 of the embodiment. FIG. 4B is another schematic diagram of FIG. 4A. FIG. 5 is a schematic diagram of the connecting box 31 of the electronic device 4 of the present invention. As shown in FIG. 4A, the electronic device 4 comprises a body 41 and the connecting box 31.

Note that the connecting box 31 described in the following embodiments is applicable to an electronic device of a desktop computer, a notebook computer or a server. Although the next embodiment takes an electronic device installed in a blade server as an example, the present invention is not limited to this. Moreover, a general desktop computer, notebook computer or any other corresponding electronic device having the driving module 35 is also applicable to the present invention, and its size can be designed to be compatible to that of the electronic device 4.

As shown in FIG. 4A to FIG. 5, the body 41 comprises a first opening 311 and an accommodating space corresponding to the first opening 311. The body 41 further comprises a first fixing structure having a screw pole 413, a first positioning member 415 and a plurality of second positioning members 417. According to the embodiment, the first positioning member 415 or the second positioning members 417 are protruding plates, protruding bumps, stoppers, protruding ribs, protruding dots or any other equivalent structures.

The connecting box 31 is used for accommodating the driving module 35. The connecting box 31 is installed through the first opening 311 in the accommodating space and coupled to the electronic device 4. Accordingly, the connecting box 31 has a cross section slightly smaller than the opening in size. The driving module 35 corresponding to different sizes can select a compatible connecting box 31. The connecting box 31 comprises a second fixing structure having an engaging member 317 and an elastic member 315. According to the embodiment, the engaging member 317 is a screw, a screw bolt or any other equivalent structures as long as they can provide engaging and locking mechanisms. The elastic member 315 is a metal leaf spring, leaf steel, elastic slice, spring or other equivalent structures. The connecting box 31 is designed large enough to accommodate at least a housing 33.

The housing 33 is installed through the first opening 311 in the connecting box 31. The housing 33 comprises a handler 331 and a pressing member 333. One end of the handler 331 is engaged with a spring (not shown) pivoted to the housing 33 and comprises a propping portion (not shown). The other end of the handler 331 is fixed to the pressing member 333. The pressing member 333 is a push-button. The other end of the handler 331 pops if the pressing member 333 is pressed.

The driving module 35 is accommodated in the housing 33. According to the embodiment, the driving module 35 is a hard drive, and comprises a connector (not shown). According to the embodiment, the connecting box 31 is designed to accommodate two driving modules 35, and the driving module 35 is a hard drive such as a 3.5 inches hard drive.

The electronic device 4 further comprises a rear board 37 installed against a second opening 313 and coupled to the driving module 35 and a main circuit board 43. The rear board 37 is for example a circuit board, and comprises at least a connector 371 (as shown in FIG. 3) for engaging with the connector of the driving module 35. Therefore, by rotating the engaging member 317 first and then pressing the elastic member 315, the connecting box 31 can be removed from the electronic device 4.

If the connecting box 31 is to be installed in the electronic device 4, as shown in FIG. 4A, insert the connecting box 31 into an opening 411 of the electronic device 4, and push the connecting box 31 to a screw pole 413 (as shown in FIG. 4B) of the body 41. Then, the engaging member 317 is corresponding to the screw pole 413, and the elastic member 315 is fixed to the first positioning member 415, so as to lock the engaging member 317 to the screw pole 413 and fix the connecting box 31 to the electronic device 4. The second positioning member 417 guides the connecting box 31 to move into the electronic device 4 and limits the displacement of two sides of the connecting box 31.

If the connecting box 31 is to be detached from the electronic device 4, as shown in FIG. 4B, first remove the electronic device 4 from a rack (not shown), then rotate the engaging member 317 from the screw pole 413, further press the elastic member 315, and enable the connecting box 31 to move toward a direction indicated by arrow A, so as to detach the connecting box 31 from the electronic device 4. Therefore, its assembly and detach steps are very simple.

If the driving module 35 is to be detached from the connecting box 31, as shown in FIG. 3, first press the pressing member 333 of the housing 33 to enable the other end of the handler 331 to be popped, and then push the handler 331. In the meantime, the propping portion (not shown) of the handler 331 is propping a side edge (not shown) of the connecting box 31 automatically, so as to push the housing 33 from the connecting box 31 and acquire the driving module 35. Therefore, the connecting box 31 can provide the driving module 35 supporting a hot-swappable function. When the driving module 35 in different size is to be replaced, only to detach the connecting box 31, without the replacement of the electronic device 4, and having the efficiency of cost saving.

### Second Embodiment

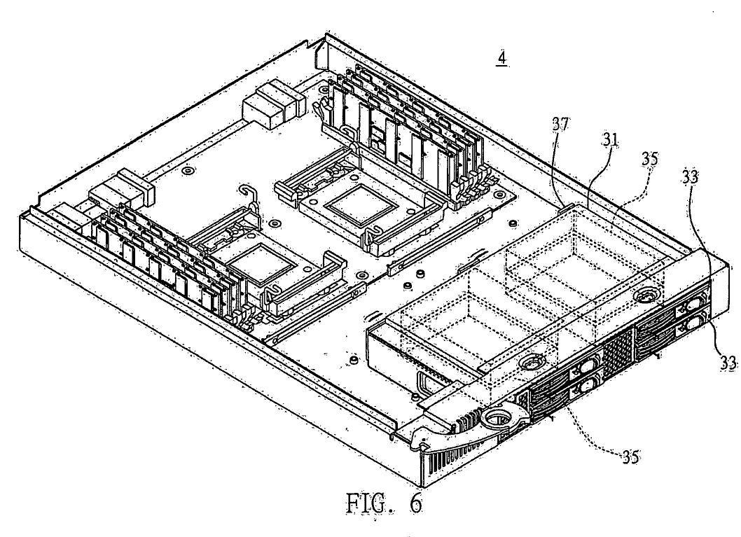

Please refer to FIG. 6, which is a schematic diagram of the electronic device 4 for at least a driving module of a second embodiment. The same reference symbols denote the portions having the same functions as in the first embodiment, and a detailed description thereof will be omitted. A difference between the preferred embodiment and the first embodiment is that the connecting box 31 can accommodating four driving modules 35, and the driving module 35 is for example a 2.5 inches hard drive.

However, in the above embodiments, although a certain number of the driving modules 35 of a certain size are used for illustrating a structural design of the connecting box 31 of the present invention, note that in other embodiments the structural design of the connecting box 31 can be changed in accordance with a number and size structure of the driving module 35, and the present invention is not limited to be the embodiments mentioned previously.

In summary, the present invention has a low manufacturing cost, provides the connection box 31 a hot-swappable function, can be provided with the driving module 35 of different sizes, can provide simple assembling and detaching steps, and solves the drawbacks that the prior art increases the cost and cannot be assembled with driving modules of different sizes. The present invention is therefore evaluated to be of high industry utility.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. An electronic device for at least a driving module, the electronic device comprising:
a body comprising an opening, an accommodating space corresponding to the opening, and a first fixing structure installed adjacent to the accommodating space; and
a connecting box for accommodating the driving module and for allowing the driving module to be replaced through the opening into the accommodating space, the connecting box comprising a second fixing structure corresponding to the first fixing structure for fixing the connecting box in the body.

2. The electronic device of claim 1, wherein the first fixing structure comprises a screw pole, a first positioning member, and a plurality of second positioning members, all of which are installed around a peripheral region of the accommodating space.

3. The electronic device of claim 2, wherein the first positioning member is one selected from the group consisting of a protruding plate, a protruding bump and a stopper.

4. The electronic device of claim 2, wherein the second positioning member is one selected from the group consisting of a protruding plate, a protruding bump, a stopper, a protruding rib and a protruding dot.

5. The electronic device of claim 1, wherein the second fixing structure comprises an engaging member installed on a side surface of the connecting box, and an elastic member.

6. The electronic device of claim 5, wherein the engaging member is one selected from the group consisting of a screw and a screw bolt.

7. The electronic device of claim 5, wherein the elastic member is one selected from the group consisting of a metal leaf spring, a leaf steel, a spring slice and a spring.

8. The electronic device of claim 1 further comprising a housing installed on a side of the connecting box, the housing comprising a handler and a pressing member.

9. The electronic device of claim 1, wherein the driving module is a hard drive.

10. The electronic device of claim 1 further comprising a rear board for electrically connecting the body and the driving module in the connecting box.

11. The electronic device of claim 10, wherein the rear board is a circuit board and comprises at least a connector.
